(19) United States
(12) Patent Application Publication
(10) Pub. No.: US 2014/0183709 A1
(43) Pub. Date: Jul. 3, 2014

(54) COMPARTMENTALIZED HEAT SPREADER FOR ELECTROMAGNETIC MITIGATION

(71) Applicant: INTERNATIONAL BUSINESS MACHINES CORPORATION, Armonk, NY (US)

(72) Inventors: Don A. Gilliland, Rochester, MN (US); Dennis J. Wurth, Rochester, MN (US)

(73) Assignee: International Business Machines Corporation, Armonk, NY (US)

(21) Appl. No.: 13/732,627

(22) Filed: Jan. 2, 2013

(51) Int. Cl. H01L 23/552; H01L 21/56

(52) U.S. Cl. CPC H01L 23/552; H01L 21/56
USPC 257/659; 438/127

(57) ABSTRACT

An approach for compartmentalizing heat spreaders within an integrated circuit package is provided. In one aspect, the approach comprises a shielding member that is connected to the integrated circuit package. The shielding member is further adapted to provide a shielded enclosure to the integrated circuit package, wherein the shielded enclosure contains an internal cavity filled with frequency absorber material to dissipate radio frequency energy emitted by the integrated circuit package. In another aspect, the shielding member comprises compartments including an outer vertical layer, a top layer, and an inner vertical layer that provides heat transfer from the heat spreader to the top layer of the shielding member. In addition, the heat is transferred from the top layer of the compartments of the shielding member to a heat sink of the integrated circuit package.

### FIELD OF THE INVENTION

The present invention relates generally to integrated circuits, and more particularly to a compartmentalized heat spreader for electromagnetic mitigation on the integrated circuits.

### BACKGROUND OF THE INVENTION

Electromagnetic waves generated by components of integrated circuits (IC) or electronic devices in general can negatively impact electronic equipment and communication receivers. Such effects are generally known as Electromagnetic Interference (EMI) or Radio Frequency Interference (RFI). For example, EMI or RFI can cause disruption of signals utilized in the ICs. Furthermore, EMI or RFI can also cause external ambient interference with the ICs or the electronic devices. To prevent negative impacts of EMI or RFI, shielding agents can be used on the ICs or electronics devices as protective or containment shields. Specifically, the shielding agents can utilize conductive enclosures to reflect or contain electromagnetic energy on the ICs or the electronic devices. However, a solution is required that not only shields the IC or the electronic devices, but also provides dissipation for undesired EMI or RFI.

### SUMMARY

In one embodiment of the present invention, an integrated circuit package is provided, the integrated circuit package comprises a shielding member connected to the integrated circuit package, wherein the shielding member provides a shielded enclosure to the integrated circuit package, and wherein the shielded enclosure contains internal cavities filled with frequency absorber material to dissipate radio frequency energy emitted by the integrated circuit package. The integrated circuit package further comprises a semiconductor die having an electronic material composition of the integrated circuit package. The integrated circuit package further comprises a heat spreader having a copper layer on the semiconductor die. The integrated circuit package further comprises the shielding member comprising compartments including an outer vertical layer, a top layer, and an inner vertical layer that provides heat transfer from the heat spreader to the top layer of the shielding member, and wherein the heat is transferred from the top layer of the compartments of the shielding member to a heat sink of the integrated circuit package.

In another embodiment of the present invention, a method for compartmentalizing heat spreaders within an integrated circuit package is provided, the method comprises a shielding member providing a shielded enclosure to the integrated circuit package, wherein the shielded enclosure contains an internal cavity filled with frequency absorber material to dissipate radio frequency energy emitted by the integrated circuit package, and wherein the shielding member is connected to the integrated circuit package. The method further comprises, the shielding member providing heat transfer from heat spreaders of the integrated circuit package to compartments of the shielding member.

### BRIEF DESCRIPTION OF THE SEVERAL VIEWS OF THE DRAWINGS

Novel characteristics of the invention are set forth in the appended claims. The invention itself, however, as well as preferred mode of use, further objectives, and advantages thereof, will be best understood by reference to the following detailed description of the invention when read in conjunction with the accompanying Figures, wherein, like reference numerals indicate like components, and:

FIG. 1 illustrates an integrated circuit material package comprising a silicon die and a heat spreader, in accordance with an embodiment of the present invention.

FIG. 2 illustrates heat spreaders in contact with multichip modules on a printed circuit board, in accordance with an embodiment of the present invention.

FIG. 3 illustrates compartments with internal cavities of thermal conductive materials, in accordance with an embodiment of the present invention.

FIG. 4 illustrates thermal conductive materials with internal cavities filled with radio frequency absorber material, in accordance with embodiments of the present invention.

FIG. 5 illustrates an alternative embodiment of compartments of FIG. 3 with internal cavities of thermal conductive materials, in accordance with embodiments of the present invention.

FIG. 6 illustrates a top lid of a thermal conductive material placed on top of compartments of FIG. 3 and heat spreaders of FIG. 1, in accordance with an embodiment of the present invention.

### DETAILED DESCRIPTION

Embodiments of the present invention comprise one or more circuits or subassemblies of circuits, as well as, methods that provide shielded enclosures for an Integrated Circuit (IC). The shielded enclosures can be attached to the IC such that they are part of the IC material package assembly. The shielded enclosures of the present invention can also be utilized to cover the IC on a circuit board or be expanded to cover multiple ICs on the circuit board. In one aspect of the present invention, perimeters of the shielded enclosures can be grounded or ungrounded. According to at least one embodiment, the shielded enclosures contain internal cavities within their structure that are filled with radio frequency (RF)/microwave absorber material. The internal cavities can be resonant cavities. For example, the overall structure of the shielded enclosures are adapted to provide shielding to the IC, while the resonant cavities trap, and dissipate undesired RF energy.

In another aspect, vertical and horizontal walls of compartments of the internal cavities are constructed such that they act as heat pipes that connect to a heat spreader of the IC, and hence, transfer the heat to a top surface of the shielded enclosures, as described in further details below, in accordance with embodiments of the present invention.

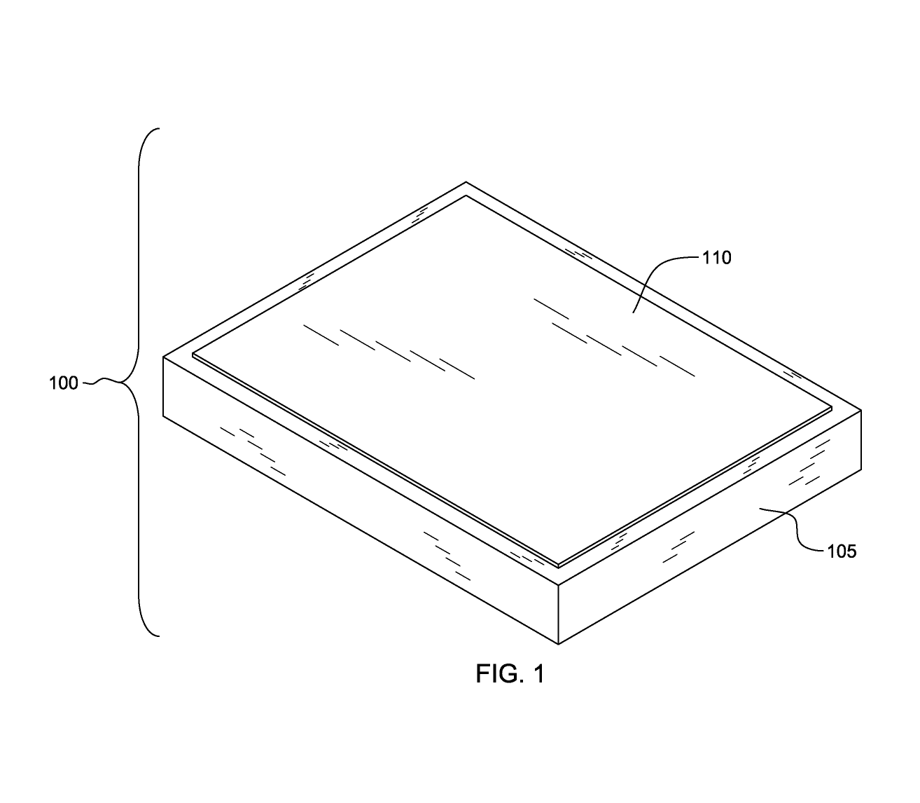

Further aspects of the present invention will now be described in conjunction with the Figures. Referring now to FIG. 1, a integrated circuit (IC) material package 100 comprising silicon die 105 and heat spreader 110 on top of silicon die 105, is depicted, in accordance with embodiments of the present invention.

Silicon die 105 is a semiconducting material on which IC material package 100 can be fabricated. Specifically, silicon die 105 includes an electronic material composition, including for example, electronic structures that would require heat to be mitigated on silicon die 105 for reliable operation of IC material package 100. In one example, silicon die 105 or substrates of silicon die 105 are susceptible to electromagnetic interference (EMI), or other environmental factors that can affect operation of IC material package 100. For example, environmental factors, such as moisture, corrosives, heat, and radiation, can negatively impact components of silicon die 105, including, for example, substrates or circuit boards of silicon die 105. In another example, silicon die 105 or substrates of silicon die 105 may produce electromagnetic emissions that could thus interfere with other electronics within or external to product enclosure containing silicon die 105. Furthermore, silicon die 105 typically generates significant heat on IC material package 100, and is consequently required to be mitigated, and cooled during operation of IC material package 100.

Furthermore, silicon die 105 comprises electrically conductive elements, such as solder bumps that connect silicon die 105 to the substrates of silicon die 105 or printed circuit boards of IC material package 100. In one aspect, the solder bumps can be formed on bond pads of silicon die 105. In another aspect, silicon die 105 includes pads on active surfaces of silicon die 105. Specifically, the pads on the active surfaces of silicon die 105 are adaptive to connect to input/output, power, or ground components of the IC material package 100, in accordance with embodiments of the present invention.

Heat spreader 110 is connected to a surface of silicon die 105 to facilitate dissipation of heat from silicon die 105. Heat spreader 110 can be adhered to a surface of silicon die 105 using thermally conductive adhesive mechanisms. Heat spreader 110 is typically a copper plate with a high thermal conductivity. For example, heat spreader 110 is an exposed copper (Cu) layer on top of silicon die 105 for thermal conductivity, and transfer of the thermal energy to a heat sink, heat pipe, or other means of mitigating heat on silicon die 105, in accordance with embodiments of the present invention. In one aspect, the heat sink is a passive heat exchanger component of IC material package 100, and is of a conductive electronic material that operates to draw heat transferred from silicon die 105. In at least one embodiment, IC material package 100 can include additional components of a typical IC or semiconductor material, in accordance with embodiments of the present invention.

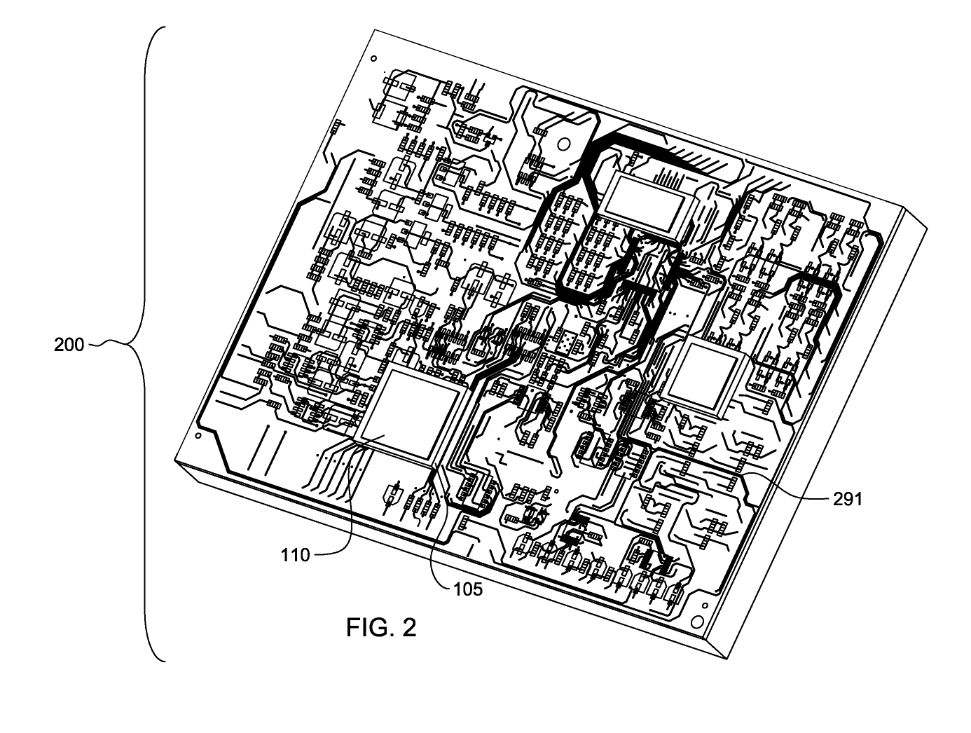

FIG. 2 illustrates heat spreader(s) 110 in contact with silicon die 105 on printed circuit board (PCB) 291 of electronic circuit 200, in accordance with an embodiment of the present invention. In the depicted embodiment, heat spreader 110 is connected to top of silicon die 105 on PCB 291. In one aspect, PCB 291 mechanically supports and electronically connects heat spreader 110 and silicon die 105 onto a substrate of electronic circuit 200.

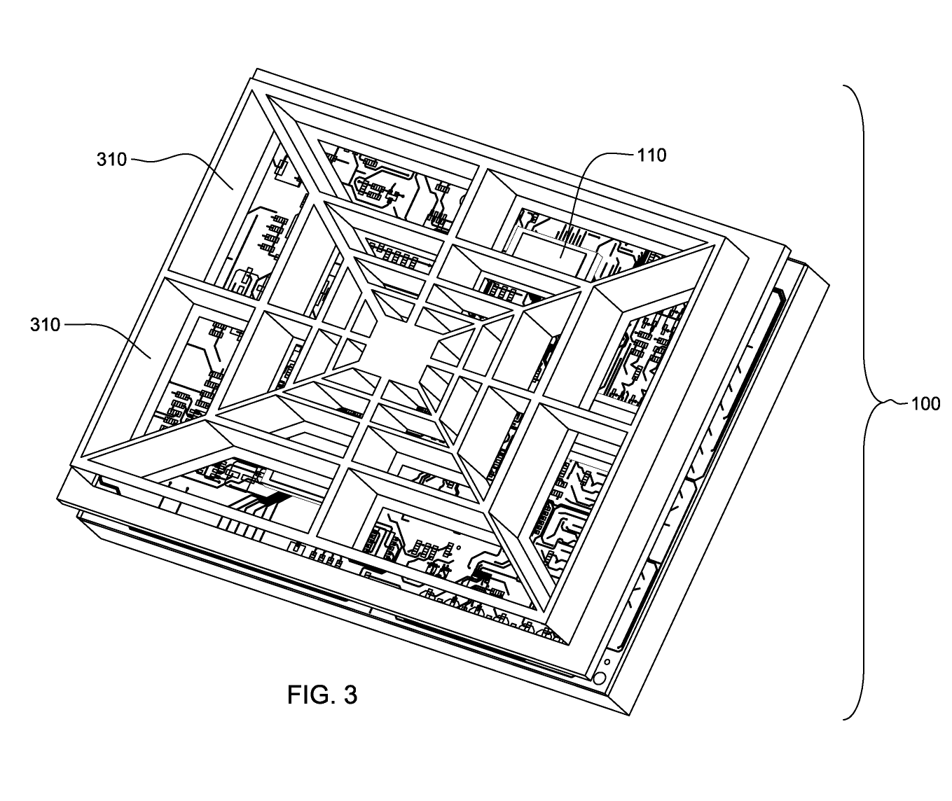

FIG. 3 illustrates compartments 310 with internal cavities of thermal conductive materials of IC material package 100, in accordance with embodiments of the present invention.

As depicted, bottom edge of vertical walls of compartments 310 terminates to a horizontal member to aid in heat transfer from heat spreader 110 of silicon die 105 to the vertical walls of compartments 310. In an alternate embodiment, compartments 310 can terminate to the horizontal member to aid in heat transfer from one or more heat spreaders 110 with thermal contact between silicon die 105 and IC material package 100. In this manner, IC material package 100 is not limited to one module of heat spreaders 110 that can conduct the heat transfer on IC material package 100.

Furthermore, the lower edges of walls of compartments 310 are adapted to widen into a base to allow additional heat to be transmitted to horizontal or vertical walls of compartments 310. The walls of compartments 310 include a slot width that can be wide enough to allow RFI or EMI emissions to enter compartments 310, in accordance with embodiments of the present invention.

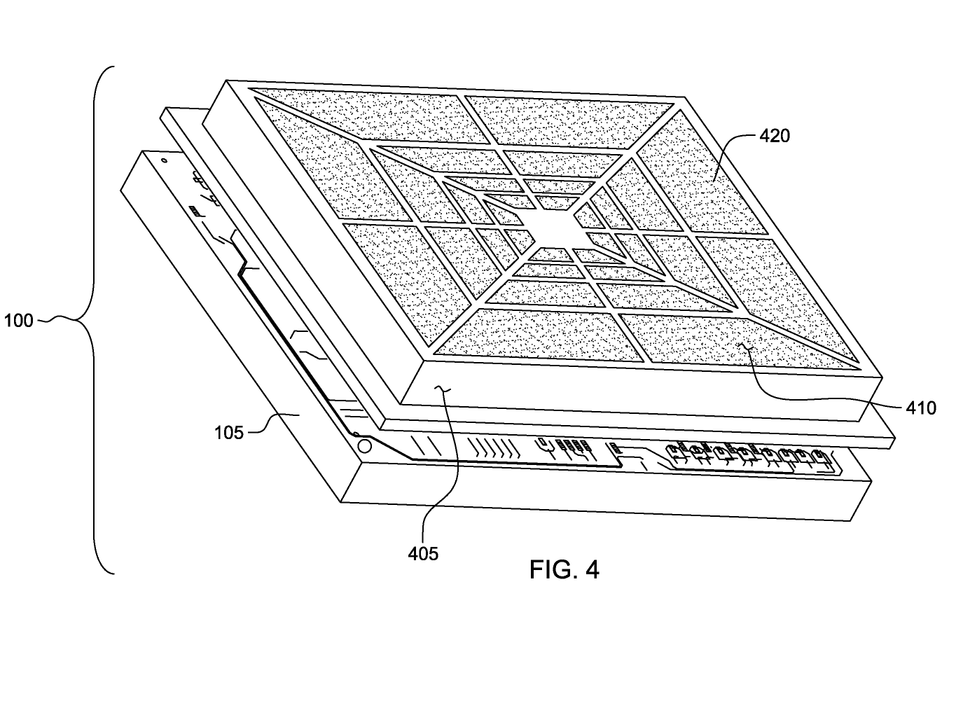

FIG. 4 illustrates thermal conductive material 405 with internal cavities 410 filled with radio frequency absorber material 420, in accordance with embodiments of the present invention. In the depicted embodiment, internal cavities 410 are configured with outer surfaces of thermal conductive material 405 to suppress electrical emissions, as discussed below.

For example, if a particular frequency is targeted, internal cavities 410 can be designed and sized to attenuate the target frequency. In one aspect, varied sizes of compartments of internal cavities 410 can address a broader band of frequencies than that of long narrow compartments of internal cavities 410. Furthermore, internal cavities 410 can be resonant cavities. The resonant cavities are chambers with dimensions to permit internal resonant oscillation of electromagnetic waves of specific frequencies, in accordance with embodiments of the present invention. Internal cavities 410 can also be varied in size or shape based on the compartments.

In particular, outer and inner vertical walls of compartments of internal cavities 410 are adapted to facilitate transfer of heat from heat spreader 110. The compartments include, for example, an outer vertical layer, a top layer, and an inner vertical layer that provides heat transfer from the heat spreader 110 to the top layer of the compartments, and wherein, the heat is transferred from the top layer of the compartments to a heat sink of IC material package 100, in accordance with embodiments of the present invention.

According to one embodiment of the present invention, transfer of heat from heat spreader 110 to a top surface of IC material package 100 allows the outer and inner vertical walls of internal cavities 410 to operate as heat spreader 110. In one aspect, internal cavities 410 are filled with radio frequency absorber material 420 to dissipate radio frequency (RF) energy emitted by IC material package 100. In one aspect, RF absorber material 420 attenuates RF energy by turning the RF energy into heat, and therefore suppresses the RF energy and dissipates it via the heat sink, heat pipe, or other means of mitigating or decreasing heat from IC material package 100, in accordance with embodiments of the present invention.

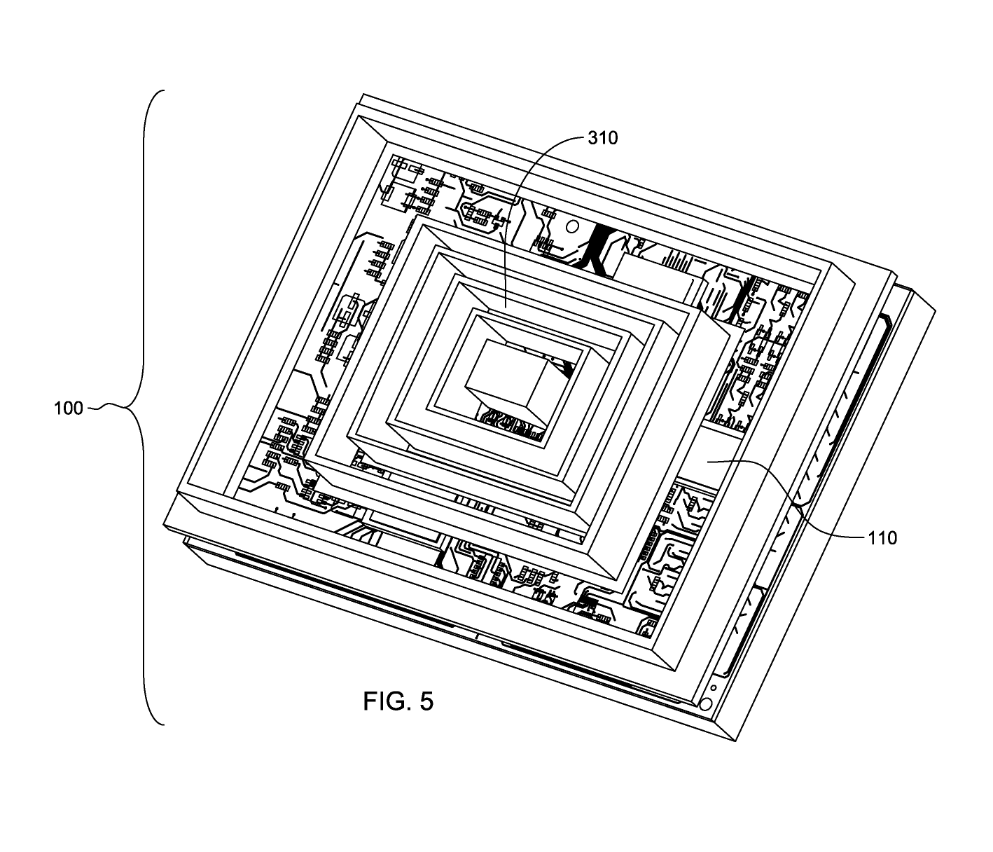

FIG. 5 illustrates an alternative embodiment of compartments of FIG. 3 with internal cavities of thermal conductive materials, in accordance with embodiments of the present invention. In the depicted embodiment, internal cavities 410 comprise different shapes, while still containing compartments 310 with internal cavities 410 of thermal conductive materials, in accordance with an embodiment of the present invention. In one embodiment, internal cavities 410 could also be filled with RF absorber material 420 as detailed in FIG. 4. Furthermore, additional vertical walls can be added to compartments 310 to address magnitude of heat flow through IC material package 100. In the depicted embodiment, heat spreader 110 is in contact with selected individual modules of multichip module 290, in accordance with embodiments of the present invention.

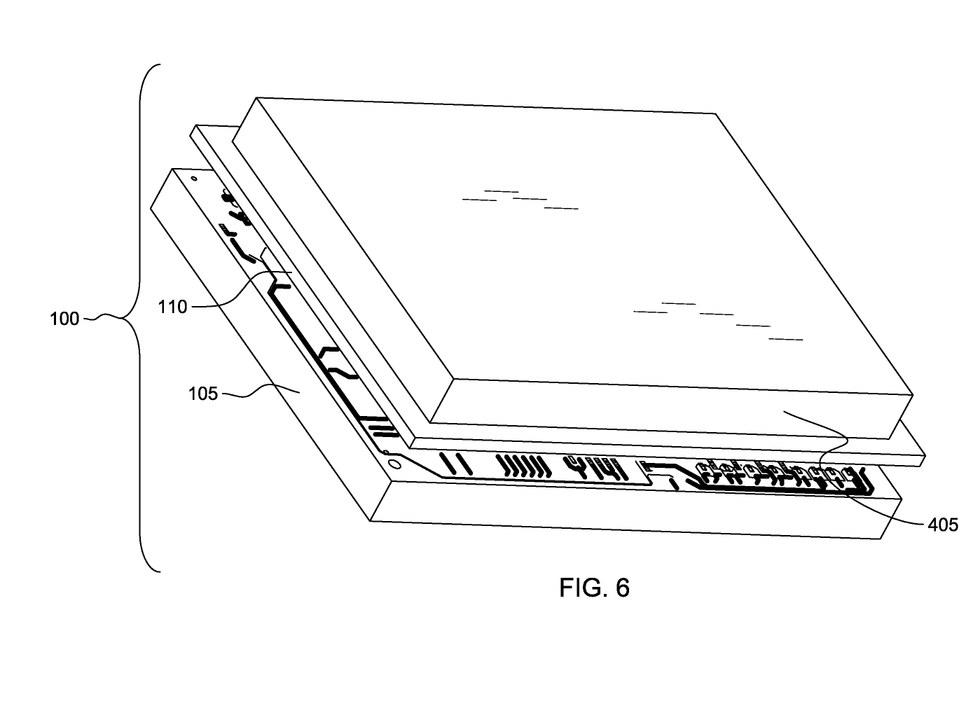

FIG. 6 illustrates a top lid of thermal conductive material 405 placed on top of compartments 310 of FIG. 3, and heat spreader 110 of FIG. 1, in accordance with an embodiment of the present invention.

In the depicted embodiment, thermal conductive material 405 is a partially enclosed framework on top of compartments 310 of FIG. 3 and heat spreader 110 of IC material package 100. Thermal conductive material 405 can be a copper (Cu) thermal material. The partially enclosed framework can be selected to affect the resonant properties of internal cavities 410, in one embodiment.

Embodiments of the present invention provide circuits or subassemblies of circuits, as well as, methods of operation, adapted to provide shielded enclosures for compartmentalizing heat spreaders an integrated circuit material package. In one aspect, embodiments of the present invention can take the form of an entirely hardware embodiment, an entirely software embodiment, or an embodiment including both hardware and software aspects that can generally be referred to herein as a “circuit” or “system”. In one embodiment, the present invention is implemented in hardware. The software can include but it is not limited to firmware, resident software, microcode, etc.

In particular, those skilled in the art can recognize that functions of circuits or subassemblies of circuits described in accordance with embodiments of the present invention can be accomplished via other means. In addition, the foregoing description of various aspects of the present invention has been presented for purposes of illustration and description. It is not intended to be exhaustive or to limit the invention to the precise form disclosed and many modifications and variations are possible.

What is claimed is:

1. An integrated circuit package, the integrated circuit package comprising:
a shielding member connected to the integrated circuit package, wherein the shielding member provides a shielded enclosure to the integrated circuit package, and wherein the shielded enclosure contains an internal cavity filled with frequency absorber material to dissipate radio frequency energy emitted by the integrated circuit package;
a semiconductor die having an electronic material composition of the integrated circuit package;
a heat spreader having a copper layer on the semiconductor die; and
the shielding member comprising compartments including an outer vertical layer, a top layer, and an inner vertical layer that provides heat transfer from the heat spreader to the top layer of the shielding member, and wherein the heat is transferred from the top layer of the compartments of the shielding member to a heat sink of the integrated circuit package.

2. The integrated circuit package according to claim 1, wherein the shielding member is adapted to connect the integrated circuit package on a circuit board.

3. The integrated circuit package according to claim 1, wherein the internal cavity is a resonant cavity.

4. The integrated circuit package according to claim 3, wherein the resonant cavity traps undesired radio frequency energy emitted by the integrated circuit package.

5. The integrated circuit package according to claim 1, wherein the compartments of the shielding member are constructed such that they act as heat pipes that connect to the heat spreader.

6. The integrated circuit package according to claim 1, wherein the frequency absorber material attenuates the radio frequency energy and converts the radio frequency energy to heat.

7. The integrated circuit package according to claim 6, wherein the converted radio frequency energy is suppressed and transferred to a heat sink of the integrated circuit package.

8. The integrated circuit package according to claim 1, wherein the vertical layer terminates to a horizontal layer to aid in heat transfer from the heat spreader to modules of the vertical layers.

9. The integrated circuit package according to claim 1, wherein lower edges of the compartments extends to allow additional heat to be transferred through the compartments to the shielding member.

10. The integrated circuit package according to claim 1, wherein the shielding member provides electromagnetic interference shielding to the integrated circuit package.

11. A method for compartmentalizing heat spreaders within an integrated circuit package, the method comprising:
a shielding member providing a shielded enclosure to the integrated circuit package, wherein the shielded enclosure contains an internal cavity filled with frequency absorber material to dissipate radio frequency energy emitted by the integrated circuit package, and wherein the shielding member is connected to the integrated circuit package; and
the shielding member providing heat transfer from heat spreaders of the integrated circuit package to compartments of the shielding member.

12. The method according to claim 11, further comprising: the shielding member connecting the integrated circuit package on a circuit board.

13. The method according to claim 11, wherein the internal cavity is a resonant cavity.

14. The method according to claim 13, wherein the resonant cavity traps undesired radio frequency energy emitted by the integrated circuit package.

15. The method according to claim 11, wherein the compartments of the shielding member are constructed such that they act as heat pipes that connect to the heat spreader.

16. The method according to claim 11, wherein the frequency absorber material attenuates the radio frequency energy and converts the radio frequency energy to heat.

17. The method according to claim 16, wherein the converted radio frequency energy is suppressed and transferred to a heat sink of an integrated circuit package.

18. The method according to claim 11, wherein the vertical layer terminates to a horizontal layer to aid in heat transfer from the heat spreader to modules of the vertical layers.

19. The method according to claim 11, wherein lower edges of the compartments extends to allow additional heat to be transferred through the compartments to the shielding member.

20. The method according to claim 11, wherein the compartments of the shielding member comprises an outer vertical layer, the top layer, and an inner vertical layer, and wherein heat is transferred from the heat spreader to the top layer of the compartments.
